(19) United States
(12) Patent Application Publication
(10) Pub. No.: US 2002/0109677 A1
(43) Pub. Date: Aug. 15, 2002

(54) Touchpad code entry system

(76) Inventor: David Taylor, Salt Lake City, UT (US)

Correspondence Address: MORRISS, BATEMAN, O'BRYANT & COMPAGNI, 136 SOUTH MAIN STREET, SUITE 700, SALT LAKE CITY, UT, 84101, US

(21) Appl. No.: 10/042,465

(22) Filed: Dec. 21, 2001

Related U.S. Application Data
(60) Provisional application No. 60/257,524, filed on Dec. 21, 2000.

(51) Int. Cl. G09G 5/00; H03K 17/94; H03M 11/00; G06F 3/00; G08C 21/00; G06K 11/16

(52) U.S. Cl. 345/173; 341/20; 708/141; 178/18.06

(57) ABSTRACT

A touchpad having a plurality of distinct zones, wherein movement of a user's finger on the surface of the touchpad between zones, the act of lifting a finger off of the touchpad surface, the act of placing a finger on the touchpad surface, and the movement of a specific pattern of a finger within a single zone are all actions that will generate characters that are transmitted from the touchpad to a receiving device. A small number of movements of a finger across the touchpad are thus capable of generating a large number of characters for use in a password or code, and thereby take advantage of the security benefits that can be achieved, but without having to memorize the exact password, but only a few movements of a finger or stylus.

### CROSS REFERENCE TO RELATED APPLICATIONS

This document claims priority to U.S. Provisional Patent No. 60/257,524, filed Dec. 21, 2000, and titled TOUCHPAD CODE ENTRY SYSTEM.

### BACKGROUND

### The Field of the Invention

This invention relates generally to rapid entry of numerical data using a touchpad. More specifically, the invention utilizes a capacitance sensitive touchpad to enter a large number of characters into a system that requires a code in order to perform a transaction, wherein the user does not have to remember the actual alphanumerical, alphabetical or numerical code in order to enter it, but instead only has to remember to move a finger in a series of patterns on a touchpad surface, wherein movement of the finger is translated into alphanumerical, alphabetical or numerical characters by a translation program embedded in the touchpad circuitry or in software.

### BACKGROUND OF THE INVENTION

The prior art in entering a code in order to open a security device is characterized by various discrete key entry systems. A typical discrete key numerical entry device is a keypad having discrete manual keys, wherein a user has to enter each discrete character of a password in order to provide the entire password to the security device. Thus, there is a one-to-one correspondence between pressing a key, and entering a single character of a code.

The usual result of a single action rendering a single character is generally the way that data is entered in devices that require a user to enter a password. For example, consider an Automatic Teller Machine (ATM). A user enters a personal identification number (PIN) into an ATM before being permitted to conduct a transaction. The PIN is 4 digits long, so 4 discrete key presses must be made on a keypad.

Another example of a discrete action resulting in the entry of a single character into a security device is an electronic lock on an office door or a vehicle door. The user will enter the code in order to gain entry, each character of the code being entered by pressing on a key on a keypad.

It is noted that most of the examples of passwords and codes that are used to open doors, access financial accounts, or to digitally encrypt and decrypt electronic documents use numbers. However, all of the discussion of numerical codes and passwords in this document should be assumed to include alphabetical characters, and alphanumerical combinations.

Security is becoming increasingly important in our complex economy of the digital era. So much information is now accessible to anyone with the proper codes that great care must be taken to secure information. But in order to provide better security, longer and longer passwords are being used in order to make the task of unauthorized access more difficult. Generally, longer passwords are more time and resource consuming tasks to break because there are more possible combinations that must be tried, when only one combination will provide access.

Passwords used with computers are becoming even more important. This is generally attributable to increased on-line electronic commerce on global information networks, such as the Internet. On-line e-commerce is also highly desirable because it is possible to conduct business in a more convenient manner. Therefore, digital signatures are becoming legitimate means for proving identity over the faceless information networks of the world. The problem is that in order to be secure, it is necessary to use long passwords.

It is generally acknowledged that nearly any code can be broken, eventually. Nevertheless, longer passwords require the dedication of significant computer processing resources in order to break them. Thus, if it will take many years of computer time to break a code, then as a practical matter, it is irrelevant and sufficiently secure for today's needs.

Accordingly, it would be an advantage over the prior art to provide a system for conveniently entering a long password, but without having to actually memorize all of the numbers used therein.

It would be another advantage over the prior art to provide a system that enables a user to generate a plurality of characters with an action that would otherwise only generate a single character. In this manner, it would be possible to enter a long password with much less action on the part of the user. The result would be a simplification of the process of entering a long but more secure password.

Finally, it would be another advantage over the prior art to enable a user to use a touchpad to enter the password. A touchpad would enable a user to ignore discrete keys, and instead only have to memorize patterns and symbols that would be essentially drawn on the surface of the touchpad with the user's finger, as opposed to having to remember a long series of numbers.

### SUMMARY OF INVENTION

It is an object of the present invention to provide a touchpad for use in the entry of a password or code, wherein the touchpad provides a plurality of zones instead of discrete keys on a surface thereof.

It is another object to provide the plurality of zones on the touchpad, wherein movement from one zone to another is representative of a single character in a password.

It is another object to provide the plurality of zones on the touchpad, wherein placing a finger on or lifting of a finger off of the touchpad surface is also representative of a character, or part of a character, or a plurality of characters.

It is another object to provide the plurality of zones on the touchpad, wherein movement of a finger through some of the plurality of zones is ignored, but laying a finger down or lifting a finger off is not.

It is another object to provide the plurality of zones on the touchpad, wherein laying a finger down or lifting a finger off in some of the plurality of zones is ignored, but movement through some of the plurality of zones is not.

It is another object to provide the touchpad wherein a particular character can only be generated by movement of a finger on the touchpad surface from a specific zone to another specific zone.

It is another object to provide the touchpad wherein the user utilizes a pattern of movement on the touchpad surface to thereby generate a desired password.

It is another object to provide the touchpad wherein the user utilizes a pattern of movement on the touchpad surface, regardless of the zone in which the movement occurs, in order to generate a desired password.

It is another object of the invention that the pattern of movement would normally be indicative of a single gesture, but in the invention is translated into the generation of multiple characters.

In a preferred embodiment, the present invention is a touchpad having a plurality of distinct zones, wherein movement of a user's finger on the surface of the touchpad between zones, the act of lifting a finger off of the touchpad surface, the act of placing a finger on the touchpad surface, and the movement of a specific pattern of a finger within a single zone are all actions that will generate characters that are transmitted from the touchpad to a receiving device. A small number of movements of a finger across the touchpad are thus capable of generating a large number of characters for use in a password or code, and thereby take advantage of the security benefits that can be achieved, but without having to memorize the exact password, but only a few movements of a finger or stylus.

In a first aspect of the invention, the touchpad is divided into a plurality of virtual zones, wherein movement into a first zone will generate a character based upon which of the other zones that a finger moved from.

In a second aspect of the invention, lifting a finger from a zone will also generate a specific character, wherein each zone will generate a unique character.

In a third aspect of the invention, a function zone which is different from all other zones is disposed within the touchpad surface, wherein movement through the function zone is ignored, but the action of placing a finger on the function zone and then lifting the finger off the function zone will perform a unique function.

In a fourth aspect of the invention, activation of the function zone performs an action, and does not generate another character.

In a fifth aspect of the invention, a total of 16 unique characters can be generated either by placing a finger in a first zone, movement from the first zone to a second zone, and then lifting a finger from the second zone.

These and other objects, features, advantages and alternative aspects of the present invention will become apparent to those skilled in the art from a consideration of the following detailed description taken in combination with the accompanying drawings.

### DESCRIPTION OF THE DRAWINGS

FIG. 1 is an illustration of a plurality of views of a touchpad , each touchpad view showing all combinations movement, and/or liftoff of a finger from the touchpad surface that will result in generating each of 12 possible unique characters when there are a total of 4 unique zones defined on the touchpad surface.

FIG. 2 is an illustration of a series of movements and liftoff that generates a particular code.

FIG. 3 is an illustration of a plurality of views of a touchpad surface, each view of the touchpad surface showing how to generate one of 16 unique characters using a combination of five unique zones.

FIG. 4 is an illustration of a series of movements and liftoff that generates a particular code.

FIG. 5 is an illustration of a series of touchdowns, movements, and liftoffs on a touchpad surface the generates a particular code.

FIG. 6 is a series of touchpad views that show an example of the movements that can be made to generate all of the letters in the English language alphabet.

FIG. 7 is a series of touchpad views that show an example of the movements that can be made to generate numbers and punctuation marks.

### DETAILED DESCRIPTION

Reference will now be made to the drawings in which the various elements of the present invention will be given numerical designations and in which the invention will be discussed so as to enable one skilled in the art to make and use the invention. It is to be understood that the following description is only exemplary of the principles of the present invention, and should not be viewed as narrowing the claims which follow.

The presently preferred embodiment of the invention is a touchpad having a total of five zones disposed thereon. Touchpad circuitry is able to detect a finger being placed anywhere on the touchpad surface, movement and position of the finger along the touchpad surface, and removal of the finger from the touchpad surface.

The touchpad of the present invention is a mutual capacitance sensitive touchpad as manufactured by CIRQUE™ Corporation. The touchpad utilizes its patented GLIDEPOINT™ technology, and can also use its GLIDETOUCH™ technology. What is important is that the touchpad be capable of detecting touchdown of a pointing device, such as a finger or stylus, on the touchpad surface, movement from one zone to a different zone, and liftoff of the pointing device from the touchpad surface.

The zones that have been mentioned in this document are simply regions of the touchpad surface that are defined by the touchpad firmware, software, and/or hardware. In other words, the sensor grid of the touchpad is able to detect the pointing device anywhere on the touchpad surface. The present invention defines arbitrarily assigned areas or regions or zones on the touchpad surface. For the convenience of the user, the zones are defined as having approximately equal amounts of surface area, and also have generally the same shape. This makes it easier for the user to consistently perform touchdown, movement through, and liftoff from the desired zones.

One of the advantages of the mutual capacitance sensitive touchpad technology of the preferred embodiment is that the user is not required to use an object other than the user's finger in order to enter characters. The convenience of using fingers is a distinct advantage. However, it is noted that the in an alternative embodiment, the present invention can utilize CIRQUE™ Corporation's GLIDEPEN technology to input characters. Instead of utilizing GLIDEPOINT™ or GLIDETOUCH™ touchpad technology, the invention would utilize magnetic pen technology. This technology utilizes a passive pen having a permanent magnet disposed therein. Accordingly, this application incorporates by reference the subject matter disclosed in pending U.S. non-provisional patent application Serial No. (Not yet assigned), and filed Nov. 22, 2001, and titled STYLUS INPUT DEVICE UTILIZING A PERMANENT MAGNET. It will become apparent that the concepts of the present invention are equally applicable to the magnetic stylus technology as to the touchpad technology. Nevertheless, it is envisioned that the touchpad technology has broader appeal and application.

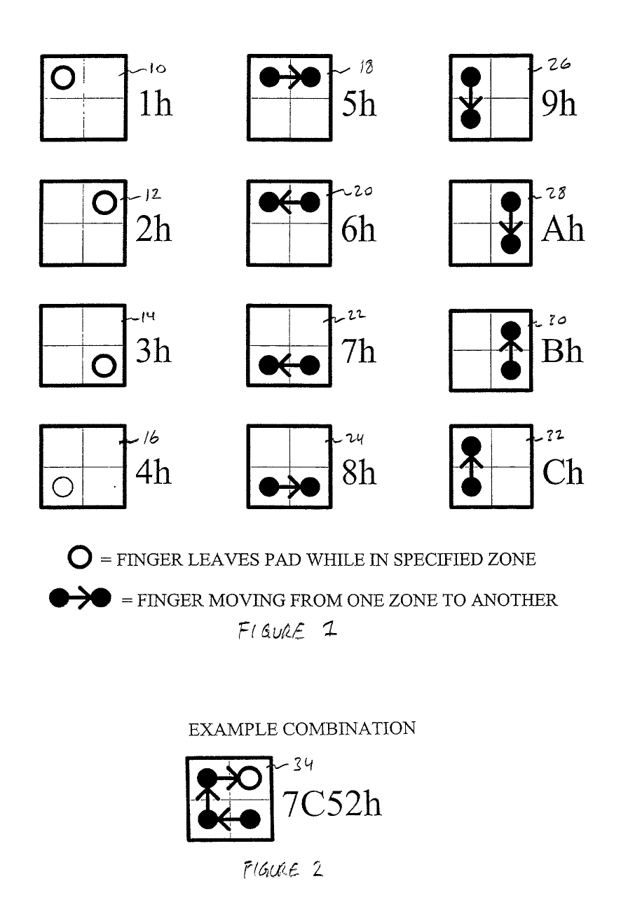

With these factors in mind, it is now possible to examine the operation of the present invention as currently implemented. FIG. 1 is an illustration of a plurality of views of a touchpad surface, each view of the touchpad surface showing all combinations of movement and/or liftoff of a finger from the touchpad surface that will result in generating each of 12 possible unique characters when there are a total of four unique zones defined on the touchpad surface.

The selection of four zones, or four zones and a fifth center zone for the touchpad is advantageous. Four zones easily enables a total of 12 unique characters to be generated using the invention. However, adding a fifth center zone makes it possible to generate 16 unique characters. In the examples to be shown 16 characters is noted for its relation to the base 16 hexadecimal numbering system. This is also important because of the relationship of hexadecimal numbers and computer technology. However, it should be remembered that more or less characters could be generated from the four or five zones by using touchdown to indicate characters. Furthermore, the total number of zones could be increased, and their arrangement modified. Thus, the preferred embodiment of five zones should not be considered limiting, but illustrative of one implementation of the novel aspects of the invention.

The 12 touchpad views in FIG. 1 show that the four equally sized touchpad zones are used to generate a character either by movement from one zone into another, or by lifting a finger off a zone. Alternatively, touchdown into a zone could also be used to represent a character. That would enable a total of 16 zones to be generated from the four zones, instead of the 12 that are illustrated.

A quick explanation of the liftoff or movement that generates a character is now provided. The touchpad views shown in FIG. 1 will be assumed to be viewed from a birds eye view, and having an upper left, lower left, upper right, and a lower right zone.

Beginning with a view of the touchpad, being called touchpad view 10, liftoff of the pointing device (hereinafter a finger) from the upper left zone results in generating the character 1h, where the symbol h represents a hexadecimal based numbering system being used. The liftoff from the upper left zone could have begun with touchdown in the same zone, or movement into the zone from the lower left or the upper right zones.

Touchpad view 12 is a liftoff from the upper right zone, and results in the character 2h. Touchpad view 14 is a liftoff from the lower right zone, and results in the character 3h. Touchpad view 16 is a liftoff from the lower left zone, and results in the character 4h. It is noted that assignment of a particular character to the action in the zones is totally arbitrary. Thus, any character can be represented by the liftoffs described above.

Touchpad view 18 shows that character 5h is generated by movement from the upper left zone to the upper right zone. This character is generated regardless of what previous actions caused the finger to be in the upper left zone to begin with. In other words, the finger could have just had touchdown in the upper left zone, could have been moved to the upper left zone from the upper right zone, or could have been moved to the upper left zone from the lower left zone. These principles apply to all of the movements described herein.

Touchpad view 20 shows that character 6h is generated by movement from the upper right zone to the upper left zone. Touchpad view 22 shows that character 7h is generated by movement from the lower right zone to the lower left zone. Touchpad view 24 shows that character 8h is generated by movement from the lower left zone to the lower right zone.

Touchpad view 26 shows that character 9h is generated by movement from the upper left zone to the lower left zone. Touchpad view 28 shows that character Ah is generated by movement from the upper right zone to the lower right zone. Touchpad view 30 shows that character

Bh is generated by movement from the lower right zone to the upper right zone. Touchpad view 32 shows that character Ch is generated by movement from the lower left zone to the upper left zone.

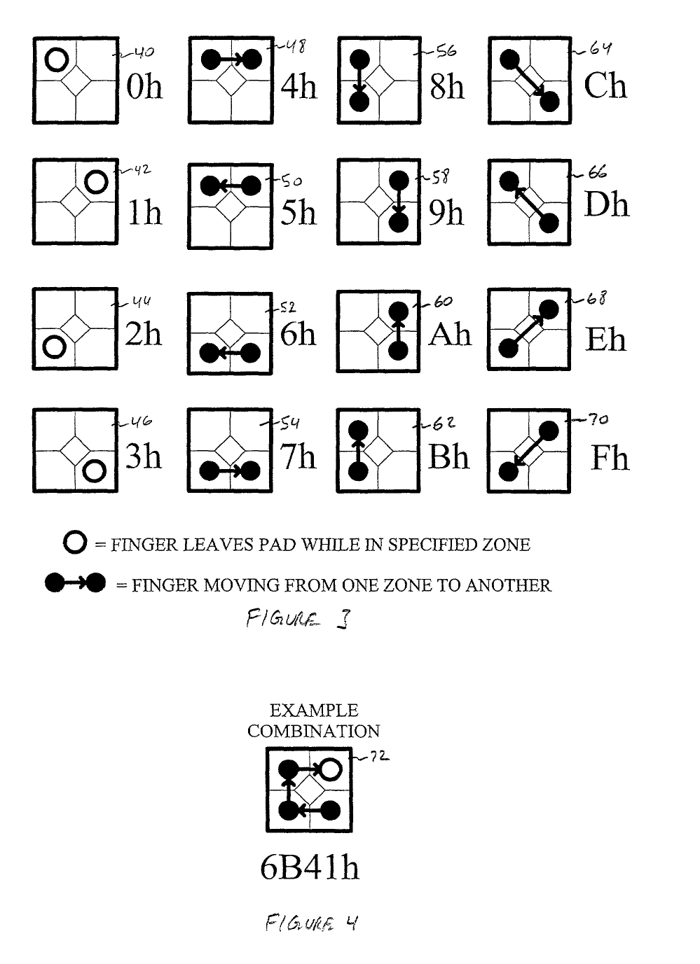

FIG. 2 is provided to illustrate a series of movements and liftoff that will generate a particular code in accordance with the rules defined above. Assume that the finger has made touchdown in the lower right zone of touchpad view 34. Movement from the lower right zone to the lower left zone generates character 7h. Movement from the lower left zone to the upper left zone generates the character Ch. Movement from the upper left zone to the upper right zone generates character 5h. Finally, liftoff from the upper right zone generates that character 2h.

There are several important observations to make. First, note that for a touchdown, one horizontal stroke, one vertical stroke, another horizontal stroke, and liftoff of the finger, a total of five movements that can also be viewed as writing the alphabetic character “C”, four characters have been generated.

Another important observation is the fact that the characters generated also need to be placed in a particular order. In other words, the characters can be generated in their order of appearance from left to right to form the sequence of numbers 7C52h. Likewise, the characters can be generated from right to left to form the sequence of numbers 25C7.

It should also be noted that if the action of touchdown was also being counted, and touchdown in the lower right zone was defined as generating the character Dh, then the same movement of drawing the alphabet character C would result in generating the five character sequence of D7C52h, or 25C7Dh, depending upon the ordering sequence chosen.

The step of generating a character from touchdown, movement, and liftoff is either hardwired into the touchpad circuitry, programmed into a software driver, or stored in firmware, as is known to those skilled in the art. For example, a table can be used to equate the actions with a character. This character can then be transmitted to whatever device or system that is waiting for input from the touchpad. Accordingly, the present invention requires the ability to transmit the characters that are generated. This can be implemented as an industry standard computer interface, or a proprietary transmission system. The means of transmission are known to those skilled in the art, and are not a limiting element of the invention. The touchpad also includes whatever hardware and/or programming that is necessary to detect touchdowns, movement, and liftoff from the zones.

It is also noted that selecting the type of characters that can be generated is a totally arbitrary decision. Thus, a touchpad of the present invention can be designed to generate numbers, alphabetical characters, or a combination of alphanumerical characters.

In order to assist the user to know the locations of the zones that the touchpad is using, a template can be disposed over the touchpad surface. The template can include a textured surface with a raised ridge between zones. The template can also be smooth, but incorporate lines to show the borders of the zones. Lines might also be manufactured into the overlay that functions as the touchpad surface.

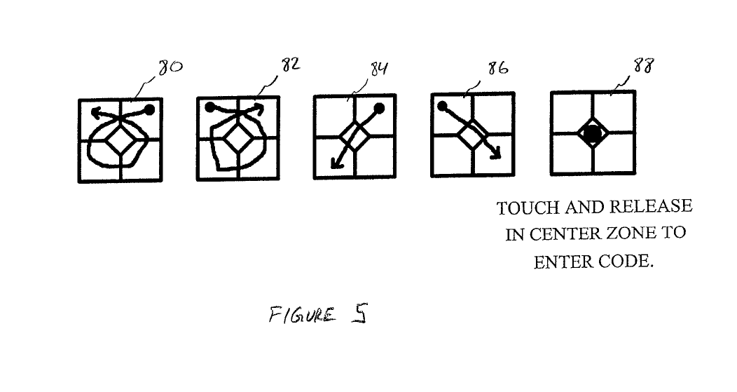

FIG. 3 is an illustration of 16 views of the same touchpad as seen from a birds eye view. The difference in the touchpad from that shown in FIG. 1 is that there is now a diamond-shaped center zone. The specific shape is not that critical, but in this case is chosen in order to be larger enough for a finger to move through without accidental contact with an unintended zone. Another factor to consider when selecting the shape of the zone is to find one that is easy to define in the hardware or software of the touchpad. Thus a circular zone may not be as precisely definable.

In FIG. 3, the center zone is being used as a function zone. In this embodiment, movement through the function zone is ignored. In the touchpad shown in FIG. 1, it was not possible to have diagonal movement between zones. The center zone now makes this possible.

The only action that will result in the touchpad performing an instruction when making contact with the center zone is from touchdown and then liftoff without any movement into a zone between performing these two steps. In this embodiment, touchdown and subsequent liftoff will result in an ENTER command being generated. However, this function can be programmed to be whatever action is desired.

For example, the function performed could be to change the sequence order of the characters that will be generated. Thus, the characters could be entered left to right, or right to left. Alternatively, it is possible that the user could even change the sequence order at any point during entry of a code. The number of times that the sequence order could be changed is entirely up to the user, but should be kept simple.

In the preferred embodiment, all of the characters that are generated since the last ENTER command was entered will be considered to be the code. Thus, this might enable grouping or editing of the characters. Another option is to enable some predetermined period of time to elapse since a character was last generated in order to empty a code buffer. A code buffer holds all of the characters that a user wants to have considered as a code. This is because it is likely that a user may have to place a finger on the touchpad, move the finger, and then remove the finger several times before enough characters have been generated to complete the password.

Before describing more benefits of this embodiment, it is useful to review an arbitrarily selected set of touchdowns, movements, and liftoffs that will generate a selected set of characters, in order to see how the center zone affects the function of the touchpad in comparison to the touchpad of FIG. 1.

Touchpad view 40 is a liftoff from the upper left zone, and results in the character 0h. Touchpad view 42 is a liftoff from the lower right zone, and results in the character 1h. Touchpad view 44 is a liftoff from the lower left zone, and results in the character 2h. Touchpad view 46 is a liftoff from the lower right zone, and results in the character 3h.

Touchpad view 48 shows that character 4h is generated by movement from the upper left zone to the upper right zone. Touchpad view 50 shows that character 5h is generated by movement from the upper right zone to the upper left zone. Touchpad view 52 shows that character 6h is generated by movement from the lower right zone to the lower left zone. Touchpad view 54 shows that character 7h is generated by movement from the lower left zone to the lower right zone.

Touchpad view 56 shows that character 8h is generated by movement from the upper left zone to the lower left zone. Touchpad view 58 shows that character 9h is generated by movement from the upper right zone to the lower right zone. Touchpad view 60 shows that character Ah is generated by movement from the lower right zone to the upper right zone. Touchpad view 62 shows that character Bh is generated by movement from the lower left zone to the upper left zone.

Unique to this embodiment is the movement between zones by passing through the center zone. Touchpad view 64 shows that character Ch is generated by diagonal movement from the upper left zone to the lower right zone. Touchpad view 66 shows that character Dh is generated by diagonal movement from the lower right zone to the upper left zone. Touchpad view 68 shows that character Eh is generated by diagonal movement from the lower left zone to the upper right zone. And lastly, touchpad view 70 shows that character Fh is generated by diagonal movement from the upper right zone to the lower left zone.

One of the key advantage of the present invention, but not the only one, is that the user only has to remember patterns or symbols, not actual numbers. The patterns could be, for example, the writing strokes that the user would normally make to spell a name, or write a well known sequence of numbers. Even writing the letters in a short word such as CAT will result in generating a large number of numbers in the preferred embodiment. Specifically, the sequence 5873E93493h could be generated. It should be apparent the remembering how to spell CAT is much easier than remembering the numerical sequence 5873E93493h. It is generally the case that it is easier to remember a few characters or symbols than it is to remember a large number. This is especially true when dealing with numbers. Even more advantageously, it can be easier to remember symbols as opposed to a randomly generated series of numbers or alphabetical characters.

For example, if a person enters a “#” symbol by tracing it on the touchpad surface shown in FIG. 3, a total of eight characters will be generated, and yet the user only had to remember one symbol.

Of course, which eight characters that will be generated depends upon which zone a user decided to begin to trace the lines of the symbol. The user could have decided on the convention of always moving top to bottom, and left to right, but this could also be changed. Thus, even the same symbol can generate many different character combinations. In this case, the four lines of the “#” symbol can be drawn 16 different ways (2⁴=16). Following the convention of top to bottom and then left to write, the combination of characters that is generated using FIG. 2 is 82934173h. However, changing the convention and performing bottom to top, and left to right will result in the combination of characters being B0A17341h. A user should decide upon and use a single convention in order to consistently enter a password.

FIG. 4 is provided to illustrate a series of movements and liftoff that will generate a particular code in accordance with the rules defined above in FIG. 3. Assume that the finger has made touchdown in the lower right zone of touchpad view 72. Movement from the lower right zone to the lower left zone generates character 6h. Movement from the lower left zone to the upper left zone generates the character Bh. Movement from the upper left zone to the upper right zone generates character 4h. Finally, liftoff from the upper right zone generates that character 1h. Thus, the code generated would be either 6B41h, or 14B6h, depending upon the sequence order convention being used.

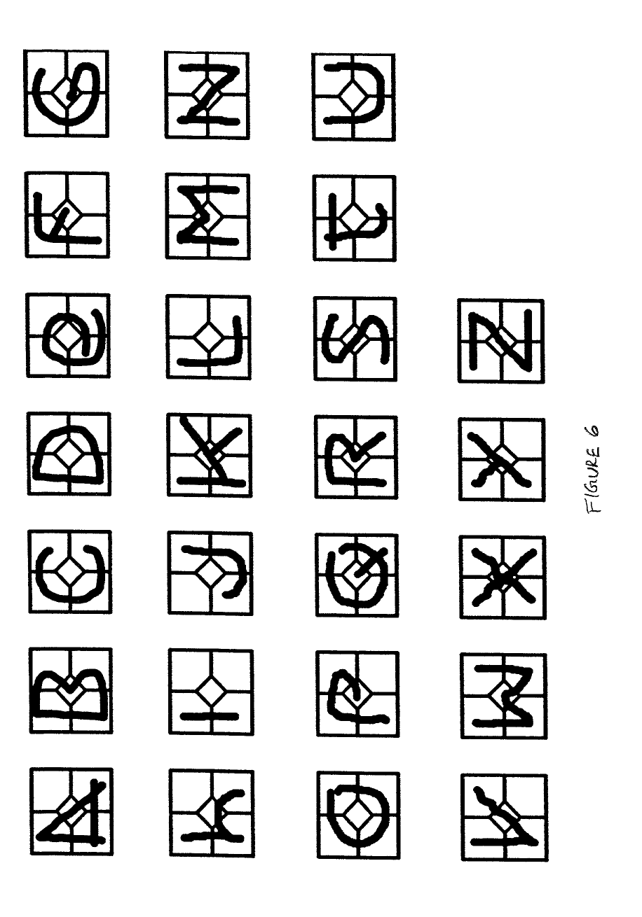

FIG. 5 is a series of views of a touchpad. Each view of the touchpad shows an example of the movements that can be made on the touchpad surface in order to enter a code. Note that in touchpad views 80 and 82, that the movements to generate characters can be continuous, and do not need to be short, discrete movements. Specifically, touchpad view 80 shows touchdown in the upper right zone, then a circular motion of the pointing device through the upper left zone, the lower left zone, the lower right zone, back into the upper right zone, and terminating in the upper left zone where there is liftoff. According to the rules of FIG. 3, the code generated would be 587A50h. Movement as shown in touchpad view 82 would generate the code 496B41h, using the same sequence order convention. Touchpad view 84 would generate the code Fh, and touchpad view 86 would generate the code Ch. Finally, touchpad view 88 would enter the code.

The present invention is also capable of generating alphabetical characters. Typically, the problem with generating such characters is that you are required to learn a new shorthand, such as GRAFITTI™ as taught by the PALM™ operating system. Advantageously, the present invention does not require this.

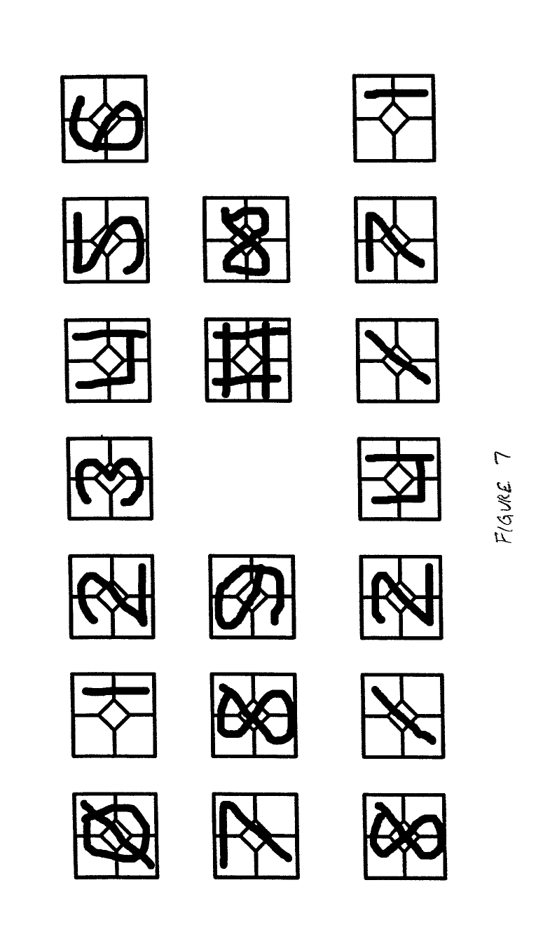

FIG. 6 is a series of touchpad views that show an example of the movements that can be made to generate all of the letters in the English language alphabet. The touchpad would be placed in a mode where instead of generating numbers, the characters would be letters of the alphabet. Most or all of the letters could be made as one continuous movement through specific zones. Note that the center zone is necessary for this particular set of movements.

FIG. 6 is a series of touchpad views that show an example of how to enable entry of numbers 0 through 9, as well as some punctuation. More movements to generate punctuation marks could be developed. These marks should only be considered illustrative of several possibilities.

The applications of the present invention are many, and are even uniquely made possible by the use of a touchpad. Possible applications include entry of digital signatures for conducting e-commerce such as an Internet transaction, accessing a financial account by entering a PIN on-line or at an ATM, and entering a code a door of a car, house or a secure area of a business. The present invention can also be used in portable electronic appliances such as PDAs and mobile telephones.

Using a touchpad as the input device can also provide advantages. For example, touchpads from CIRQUE™ Corporation can even be hidden behind solid surfaces using its HIDDEN TOUCH SURFACE™ technology. Thus, a door can appear to have no way of unlocking it, but a touchpad can be hidden beneath the surface of a wall next to the door. Only those who know of the existence of the entry pad will be able to enter the code in order to gain entry.

The present invention can even be used to secure small devices such as a safe or even a small box. The power requirements of the present invention are not large, and will enable implementation of the present invention by utilizing a battery or other isolated power source.

It is to be understood that the above-described arrangements are only illustrative of the application of the principles of the present invention. Numerous modifications and alternative arrangements may be devised by those skilled in the art without departing from the spirit and scope of the present invention. The appended claims are intended to cover such modifications and arrangements.

What is claimed is:

1. A system for generating a large number of characters in response to relatively few touchdown, movement, and liftoff actions of a pointing device on a touchpad surface, said system comprising:
a capacitance sensitive touchpad, including a touchpad surface for performing touchdown, movement, and liftoff of a pointing device on the touchpad surface;
providing a look-up table for generating a character that corresponds to each touchdown, movement, and liftoff of the pointing device on the touchpad surface; and
transmission means for transmitting the character that has been generated from the look-up table.

2. The system as defined in claim 1 wherein the system further comprises a receiving device for receiving a plurality transmitted characters from the touchpad, the plurality of transmitted characters forming a code that is utilized by the receiving device.

3. The system as defined in claim 1 wherein the look-up table is implemented in look-up table storage devices selected from the group of look-up table storage devices comprised of hardware, software, and firmware.

4. The system as defined in claim 3 wherein the capacitance sensitive touchpad further comprises a mutual capacitance sensitive touchpad.

5. The system as defined in claim 1 wherein the system further comprises a plurality of zones on the touchpad surface, wherein the plurality of zones are defined in touchpad circuitry so that it can be determined where touchdown, movement, and liftoff of the pointing device on the touchpad surface has occurred.

6. The system as defined in claim 2 wherein the transmission means further comprises an industry standard computer peripheral interface, to thereby enable the system to transmit a plurality of characters to the receiving device.

7. The system as defined in claim 6 wherein the receiving device is selected from the group of receiving devices comprised of computers, portable electronic devices, mobile telephones, security systems for providing access to a vehicle, security systems for unlocking a door, and a security interface for an automated teller machine (ATM).

8. A method for generating a large number of characters by utilizing relatively few keystrokes on a touchpad, said method comprising the steps of:
(1) providing a capacitance sensitive touchpad that is capable of detecting touchdown, movement, and liftoff of a pointing device on a surface thereof;
(2) dividing the surface of the touchpad into a plurality of zones;
(3) providing a look-up table that defines which touchdown, movement, and liftoff of the pointing device from specific zones will result in generation of characters; and
(4) generating a signal from the look-up table that is representative of a character that corresponds to action of the pointing device relative to the touchpad surface when (1) the finger moves from one zone to another zone, and (2) the finger is lifted off the touchpad surface.
